(19) United States
(12) Patent Application Publication
(10) Pub. No.: US 2011/0147735 A1
(43) Pub. Date: Jun. 23, 2011

(54) THIN FILM TRANSISTOR AND METHOD OF FORMING THE SAME

(75) Inventor: Woo-Seok Cheong, Daejeon (KR)

(73) Assignee: ELECTRONICS AND TELECOMMUNICATIONS RESEARCH INSTITUTE, Daejeon (KR)

(21) Appl. No.: 12/871,448

(22) Filed: Aug. 30, 2010

(30) Foreign Application Priority Data
Dec. 17, 2009 (KR) 10-2009-0126197

(51) Int. Cl. H01L 29/22; H01L 21/336

(52) U.S. Cl. 257/43; 438/104; 257/E29.095; 257/E21.411

(57) ABSTRACT

Provided are a thin film transistor and a method of forming the same. The thin film transistor includes: a substrate; a source electrode and a drain electrode on the substrate; an oxide active layer between the source electrode and the drain electrode; a gate electrode on one side of the oxide active layer; a gate dielectric layer between the gate electrode and the oxide active layer; and a buffer layer between the gate dielectric layer and the oxide active layer.

### CROSS-REFERENCE TO RELATED APPLICATIONS

This U.S. non-provisional patent application claims priority under 35 U.S.C. §119 of Korean Patent Application No. 10-2009-0126197, filed on Dec. 17, 2009, the entire contents of which are hereby incorporated by reference.

### BACKGROUND

1. Field

The present invention disclosed herein relates to a thin film transistor and a method of forming the same and more particularly, to a thin film transistor with an applied oxide layer and a method of forming the same.

2. Related Art

As forms of electronic devices are diversified and miniaturized, forms of transistors for operating the electronic devices also become diversified. For example, researches for a thin film transistor (which is applicable to the electronic devices) have been actively in progress. However, in a case of a previously developed thin film transistor, the uniformity or process stability of a device may not be obtained. Therefore, following-up researches for applying the thin film transistor to a device become necessary.

### SUMMARY

The present invention provides a thin film transistor with an improved reliability and a method of forming the same.

Embodiments of the present invention provide thin film transistors including: a substrate; a source electrode and a drain electrode on the substrate; an oxide active layer between the source electrode and the drain electrode; a gate electrode on one side of the oxide active layer; a gate dielectric layer between the gate electrode and the oxide active layer; and a buffer layer between the gate dielectric layer and the oxide active layer.

In some embodiments, the buffer layer may include a silicon oxide, a silicon nitride, or a combination thereof.

In other embodiments, the buffer layer may have a thickness of about 1 nm to about 20 nm.

In still other embodiments, the source/drain electrodes may be disposed adjacent to the substrate; the oxide active layer may be disposed on the substrate between the source/drain electrodes; the gate dielectric layer may be disposed on the oxide active layer; and the buffer layer may be disposed between the oxide active layer and the gate dielectric layer.

In even other embodiments, the gate electrode may be disposed adjacent to the substrate; the gate dielectric layer and the buffer layer may be sequentially stacked on the substrate including the gate electrode; the oxide active layer may be disposed on the buffer layer on the gate electrode; and the source/drain electrodes may be disposed on the buffer layer beside the active layer.

In yet other embodiments, the oxide active layer may include at least one oxide selected from Group 3A, 4A, and 5A and Group 2B, 3B, and 4B metals.

In further embodiments, the oxide active layer may include at least one of ZnO, In—Zn—O, Zn—Sn—O, In—Ga—ZnO, Zn—In—Sn—O, In—Ga—O, and SnO₂.

In still further embodiments, the gate dielectric layer may include alumina.

In other embodiments of the present invention, methods of forming a thin film transistor include: forming source/drain electrodes, a gate dielectric layer, a buffer layer contacting the gate dielectric layer, an oxide active layer, and a gate electrode, on a substrate; and performing a thermal treatment process on the gate dielectric layer and the buffer layer, wherein: the oxide active layer is formed on the substrate between the source/drain electrodes; the gate dielectric layer is formed on side of the oxide active layer; the buffer layer is formed on one side of the gate dielectric layer; and the gate electrode is spaced apart from the oxide active layer by the gate dielectric layer.

In some embodiments, the forming of the source/drain electrodes, the gate dielectric layer, the buffer layer, the oxide active layer, and the gate electrode may include: forming the gate electrode on the substrate; forming the gate dielectric layer and the buffer layer to cover the gate electrode; and forming the source/drain electrodes and the oxide active layer on the buffer layer at both sides of the gate electrode.

In other embodiments, the forming of the source/drain electrodes, the gate dielectric layer, the buffer layer, the oxide active layer, and the gate electrode may include: forming the source/drain electrodes and the oxide active layer on the substrate; forming the buffer layer and the gate dielectric layer to cover the oxide active layer; and forming the gate electrode on the gate dielectric layer.

In still other embodiments, the thermal treatment may be performed under a temperature of about 100° C. to about 300° C.

In even other embodiments, the gate dielectric layer may include alumina.

In yet other embodiments, the buffer layer may include a silicon oxide, a silicon nitride, or a combination thereof, and may be formed under a room temperature to a temperature of about 500° C.

In further embodiments, the buffer layer may be formed through a plasma enhanced chemical vapour deposition method.

In still further embodiments, the oxide active layer may include: at least one oxide selected from Group 3A, 4A, and 5A and Group 2B, 3B, and 4B metals.

In even further embodiments, the gate electrode and the source/drain electrodes may include at least one selected from a metal and a metal oxide.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a schematic diagram of a thin film transistor according to one embodiment of the present invention;

FIGS. 2 and 3 are views illustrating modifications of one embodiment of the present invention;

FIG. 4 is a view illustrating a thin film transistor according to another embodiment of the present invention;

FIG. 5 is a view illustrating modifications of another embodiment of the present invention; and

FIG. 6 is a view illustrating effects of embodiments of the present invention.

### DETAILED DESCRIPTION OF EMBODIMENTS

Hereinafter, a transferred thin film transistor and a method of forming the same will be described according to an embodiment of the present invention with reference to the accompanying drawings. Described embodiments below are provided to allow those skilled in the art to understand the scope of the preset invention, but the present invention is not limited thereto. Embodiments of the present invention may be modified in other forms within the technical idea and scope of the present invention. In the specification, ‘and/or’ means that it includes at least one of listed components. These terms are only used to distinguish one element from another element. It will also be understood that when a layer (or film) is referred to as being ‘on’ another layer or substrate, it can be directly on the other layer or substrate, or intervening layers may also be present. It will be understood that although the terms first and second are used herein to describe various elements, these elements should not be limited by these terms. In the figures, the dimensions of layers and regions are exaggerated for clarity of illustration.

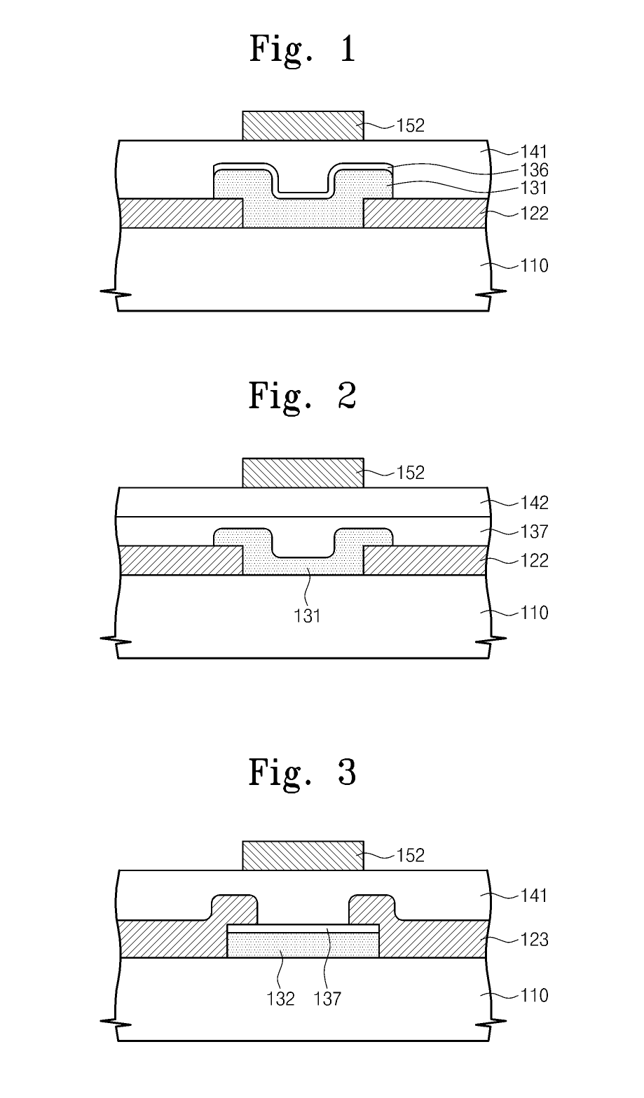

Referring to FIG. 1, a thin film transistor according to one embodiment of the present invention will be described below.

FIG. 1 is a schematic diagram of a thin film transistor according to one embodiment of the present invention. A substrate 110 is prepared. The substrate 110 may be a semiconductor substrate, a glass substrate, or a plastic substrate, but is not limited thereto.

Source/drain electrodes 122 may be disposed on the substrate 10. The source/drain electrodes 122 may include conductive materials selected from a group consisting of a metal and a metal oxide. In the one embodiment, the source/drain electrodes 122 may be a transparent conductive layer. For example, the source/drain electrodes 122 may include Indium Tin Oxide (ITO) or Indium Zinc Oxide (IZO). Alternatively, the source/drain electrodes 122 may be an opaque conductive layer. For example, the source/drain electrodes 122 may include at least one of metals including Mo and Au/Ti.

An active layer 131 may be disposed between the source/drain electrodes 122 on the substrate 110. The active layer 131 may be a layer including a region where a channel is generated during an operation of a thin film transistor. The active layer 131 may include an oxide. In the one embodiment, the active layer 131 may include at least one of Zn, In, Ga, and Sn. For example, the active layer 131 may be ZnO—SnO₂, ZnO—In₂O₃—SnO₂, In₂O₃—Ga₂O₃—ZnO or In₂O₃—ZnO.

A gate dielectric layer 141 may be disposed to cover the active layer 131 and the source/drain electrodes 122. The gate dielectric layer 141 may include at least one of insulating materials including a metal oxide, a metal nitride, a metal oxynitride, a nonmetal oxide, a nonmetal nitride, and a nonmetal oxynitride. For example, the gate dielectric layer 141 includes alumina Al₂O₃.

A buffer layer 136 may be interposed between the active layer 131 and the gate dielectric layer 141. Unlike the drawings, the buffer layer 136 may include a plurality of layers. The buffer layer 136 may have a thickness of about 1 nm to about 20 nm. The buffer layer 136 may include SiNx, SiOx, or a combination thereof. In one embodiment, the buffer layer 136 may be a thermally treated insulation layer.

Due to the buffer layer 136, a device characteristic of a thin film transistor including the buffer layer may be improved. For example, the buffer layer 136 may reduce electrical stress between the gate dielectric layer 141 and the active layer 131. In more detail, the buffer layer 136 may prevent occurrence of a trap site at the interface of the gate dielectric layer 141. The reduction of the trap site may improve interface characteristic and thus, electron mobility may be improved in the thin film transistor. Accordingly, a subthreshold slope (SS) value characteristic of a thin film transistor including the buffer layer 136 may be improved. That is, reliability of a thin film transistor may be improved.

A gate electrode 152 may formed on the gate dielectric layer 141. The gate electrode 152 may be a conductive layer. In one embodiment, the gate electrode 152 may be a transparent conductive layer. For example, the gate electrode 152 may include ITO or IZO. Alternatively, the gate electrode 152 may be an opaque conductive layer. For example, the gate electrode 152 may include at least one of metals including Mo, Pt, and Au/Ti.

Component arrangement in the thin film transistor may be variously modified within the scope of the present invention.

Referring to FIG. 2, the buffer layer 137 may cover whole top surface and whole sidewalls of the active layer 132. Unlike the drawings, the buffer layer 137 and the gate dielectric layer 142 may be conformally formed on the top surfaces of the source/drain electrodes 122 and the active layer 132. Forms of the buffer layer 137 and the gate dielectric layer 142 may be variously modified according to characteristics of used materials and/or formation methods.

Referring to FIG. 3, a portion of the source/drain electrodes 123 may be disposed on the edge portion of the active layer 132. That is, the source/drain electrodes 123 may not be flat. In this case, the buffer layer 137 may cover whole top surface of the active layer 132 and separates the partial top surface of the active layer 132 below the source/drain electrodes 123 from the gate dielectric layer 141. Besides that, forms of the source/drain electrodes 123 and the active layer 131 may be variously modified according to characteristics of used materials and/or formation methods.

Referring to FIG. 1 again, the method of forming a thin film transistor according to one embodiment of the present invention will be described below. Descriptions about the above-mentioned components may be omitted.

Referring to FIG. 1, source/drain electrodes 122 are formed on the substrate 110. After a conductive thin layer is coated on the substrate 110, the source/drain electrodes 122 may be formed by etching the conductive thin layer. The conductive thin film may be a transparent conductive layer or an opaque conductive layer. For example, the conductive thin film may include ITO.

The active layer 131 may be formed on the source/drain electrodes 122. The active layer 131 may be selected from oxides having a semiconductor characteristic. For example, the active layer 131 may include at least one selected from a group consisting of Zn, In, Ga, and Sn. The active layer 131 may be deposited by a physical deposition method or a chemical deposition method. In one embodiment, the active layer 131 may be formed by the physical deposition method. For example, the active layer 131 may be formed through a physical vapour deposition (PVD) method or an ion-beam deposition method.

The buffer layer 136 and the gate dielectric layer 141 may be formed on the active layer 131. The buffer layer 136 may be conformally formed on the active layer 131.

The buffer layer 136 may include SiNx, SiOx, or a combination thereof. The buffer layer 136 may be formed through one of various layer formation methods including an atomic layer deposition method and a plasma enhanced chemical vapour deposition method.

The active layer 131 and the buffer layer 136 may be patterned. The active layer 131 and the buffer layer 136 may be patterned continously. According to this, the top surface of the source/drain electrodes 122 may be exposed. The above patterning includes forming and patterning a photoresist layer on the buffer layer 136 and etching the buffer layer 136 and the active layer 131 using the patterned photoresist layer as an etching mask. The etching process may be wet etching, dry etching, ion-milling or combination thereof. Unlike this, the patterning of the active layer 131 may be performed before the forming of the buffer layer 136. Referring to FIG. 2, after the forming and patterning of the active layer 131, the buffer layer 137 may be formed on the patterned active layer 131. In this case, a pattering process for the buffer layer 137 may be omitted.

The gate dielectric layer 141 may include at least one of an oxide layer, a nitride layer, and a combination thereof, which have no mobile charge. The gate dielectric layer 141 may be formed with a single layer or a multi layer. For example, the gate dielectric layer 141 includes alumina Al₂O₃. The gate dielectric layer 141 may be formed through one of layer formation methods including an atomic layer deposition method, a plasma enhanced chemical vapour deposition method, and a metalorganic chemical vapour deposition method.

After the forming of the gate dielectric layer 141, a thermal treatment process may be performed. The thermal treatment process includes providing a heat of 100° C. to 300° C. on the gate dielectric layer 141 and the buffer layer 136. By the thermal treatment process, interface characteristic between the gate dielectric layer 141 and the active layer 131 may be improved. For example, by the formation and thermal treatment process of the buffer layer 136, defect such as dangling bonding of the surface of the gate dielectric layer 141 may be removed. According thereto, a trap site at an interface between the gate dielectric layer 141 and the active layer 131 may be reduced and also electron mobility may be improved. Accordingly, a device characteristic of a thin film transistor including the buffer layer 136 may be improved.

The gate electrode 152 may be formed on the gate dielectric layer 141. After the forming of a conductive thin layer on the gate dielectric layer 141, the gate electrode 152 may be formed by patterning the conductive thin layer. Alternatively, the gate electrode 152 may be formed by a pattern formation process that does not require a etching process, for example, a printing method.

The source/drain electrodes 122, the active layer 131, and the buffer layer 136 may be formed with a different order. Referring to FIG. 3, after the forming of the active layer 132 and the buffer layer 137 on the substrate 110, the source/drain electrodes 123 may be formed on the active layer 132 and the buffer layer 137 on the substrate 110. The gate dielectric layer 141 may be formed on the buffer layer 137 and the source/drain electrode 123, and then a thermal treatment process may be performed.

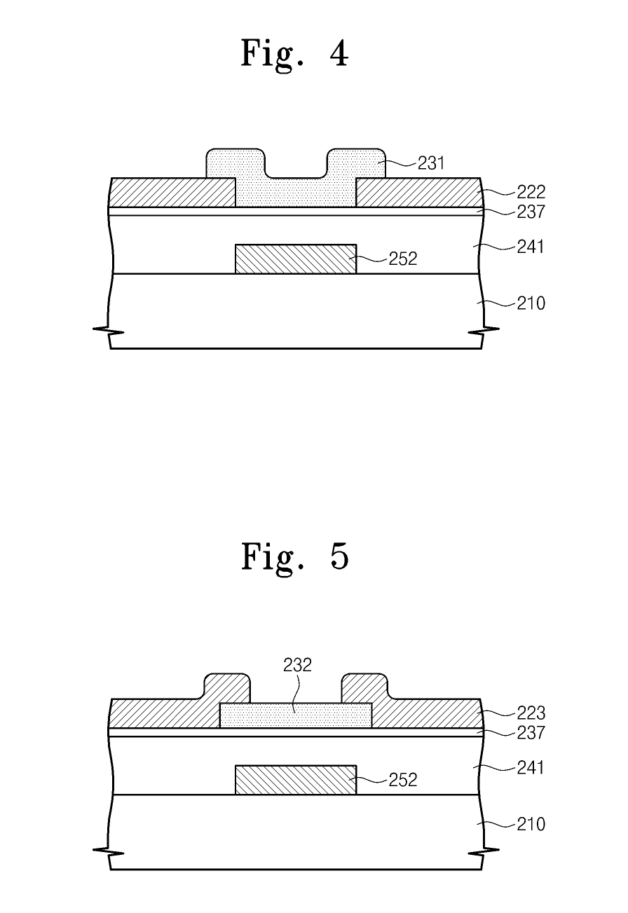

Referring to FIG. 4, a thin film transistor according to another embodiment of the present invention will be described. A gate electrode 252 may be disposed on a substrate 210. The gate electrode 252 may include at least one of conductive materials including a metal and a metal oxide. In one embodiment, the gate electrode 252 may be a transparent conductive layer. For example, the gate electrode 252 may include ITO or IZO. Alternatively, the gate electrode 252 may be an opaque conductive layer. For example, the gate electrode 252 may include at least one of metals including Mo, Pt, and Au/Ti.

A gate dielectric layer 241 may be formed on the gate electrode 252. The gate dielectric layer 241 may cover the top surface and sides of the gate electrode 252. The gate dielectric layer 241 may include at least one of insulating materials including a metal oxide, a metal nitride, a metal oxynitride, a nonmetal oxide, a nonmetal nitride, and a nonmetal oxynitride. For example, the gate dielectric layer 241 includes alumina Al₂O₃.

A buffer layer 237 may be disposed on the gate dielectric layer 241. The buffer layer 237 may have a thickness of about 1 nm to about 20 nm. The buffer layer 237 may cover an entire surface of the gate dielectric layer 241. The buffer layer 237 may include SiNx, SiOx, or a combination thereof. In one embodiment, the buffer layer 237 may be a thermally treated insulation layer.

Source/drain electrodes 222 may be disposed on the buffer layer 237. The Source/drain electrodes 222 may be a transparent conductive layer. For example, the gate electrode 222 may include ITO or IZO. Alternatively, the source/drain electrodes 222 may be an opaque conductive layer. For example, the source/drain electrodes 222 may include at least one of metals including Mo and Au/Ti.

An active layer 231 may be disposed on on the buffer layer 237. An edge portion of the active layer 231 may be overlapped with portions of the source/drain electrodes 222. That is, both edges of the active layer 231 are disposed on the edge of the source/drain electrodes 222, and the middle portion of the active layer 231 may be disposed on the gate dielectric layer 241 and the buffer layer 237 on the gate electrode 252. The active layer 231 may be a layer including a region where a channel is genetated during an operation of a thin film transistor. The active layer 231 may include oxide. In one embodiment, the active layer 231 may include a oxide of at least one of Zn, In, Ga, and Sn. For example, the active layer 231 may be ZnO—SnO₂, ZnO—In₂O₃—SnO₂, In₂O₃—Ga₂O₃—ZnO or In₂O₃—ZnO.

Alternatively, the source/drain electrodes 222 and the gate electrode 252 may be disposed with different forms. Referring to FIG. 5, an active layer 232 may be disposed on the buffer layer 237, and source/drain electrodes 223 may be disposed on both edges of the active layer 232. The source/drain electrodes 223 may extend from the both edges of the active layer 232 to on the gate dielectric layer 241 and the buffer layer 237.

Referring to FIG. 4, a method of forming a thin film transistor according to another embodiment of the present invention will be described.

The gate electrode 252 may be formed on the substrate 210. After forming of a conductive thin film on the substrate 210, the gate electrode 252 may be formed by performing a patterning process.

The gate dielectric layer 241 may be formed on the gate electrode 252. The gate dielectric layer 241 may be formed with a single layer or a multi layer. The gate dielectric layer 241 may include at least one of insulating materials including a metal oxide, a metal nitride, a metal oxynitride, a nonmetal oxide, a nonmetal nitride, and a nonmetal oxynitride. For example, the gate dielectric layer 241 includes alumina Al₂O₃.

The buffer layer 237 may be formed on the gate dielectric layer 241. The buffer layer 237 may include SiNx, SiOx, or a combination thereof. Alternatively, the buffer layer 237 may include a plurality of layers. After the forming of the buffer layer 237, a thermal treatment process may be performed. The thermal treatment process may be performed under a temperature of about 100° C. to 300° C. The thermal treatment process may be performed before forming an active layer (which will be described later) and after the forming of the gate dielectric layer 241 and the buffer layer 237, or may be performed after the forming of the gate dielectric layer 241, the buffer layer 237, and the active layer.

Interface characteristic of the gate dielectric layer 241 may be improved due to the formation of the buffer layer 237 and the thermal treatment process. In more detail, defects at the surface of the gate dielectric layer 241 contacting the buffer layer 237 may be removed due to the buffer layer 237 and the thermal treatment process. Accordingly, occurrence of a trap site in the gate dielectric layer 241 may be minimized. Accordingly, reliability of a thin film transistor including the buffer layer 237 and the gate dielectric layer 241 may be improved.

The source/drain electrodes 222 may be formed on the buffer layer 237. The active layer 231 may be formed on the buffer layer 237 between the source/drain electrodes 222. The active layer 231 may include an oxide. As shown in FIG. 4, the active layer 231 may extend on the edges portion of the source/drain electrodes 222. The active layer 231 may overlap the gate electrode 252. The middle portion of the active layer 231 overlaps the gate electrode 252 vertically, and the edges of the active layer 231 overlap the source/drain electrodes 222. In this case, after the forming of the source/drain electrodes 222 on the buffer layer 237, the active layer 231 may be formed.

The source/drain electrode 222 and the active layer 231 may be formed in different forms. Referring to FIG. 5, after the forming of the active layer 232 on the buffer layer 237, the source/drain electrode 223 may be formed. In this case, the edges of the source/drain electrodes 223 are formed to extend on the edges of the active layer 232.

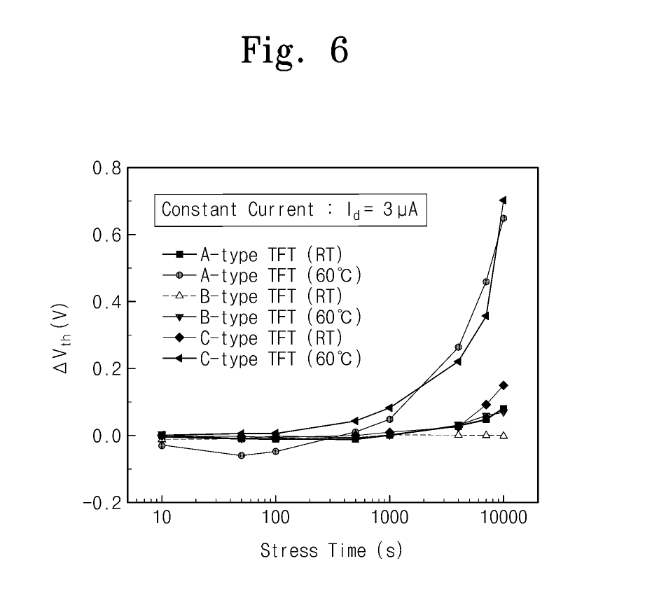

Referring to FIG. 6, effects based on embodiments of the present invention will be described. FIG. 6 is a graph illustrating a threshold voltage variation according to time with a contact current of thin film transistors, which are formed according to embodiments of the present invention.

Thin film transistors of three types are used in this experimental example. In common, a glass substrate is used for a substrate, and an ITO layer is used for source/drain electrodes and a gate electrode. The source/drain electrode and the gate electrode have a thickness of about 150 nm. An active layer is formed of Indium Gallium Zinc Oxide. An alumina layer is used for a gate dielectric layer, and the gate dielectric layer is formed with a thickness of about 180 nm. In a constant current of 3 μA, variation of a threshold voltage according to a stress time is measured. A threshold voltage value is measured under a temperature condition of a room temperature and below 60° C.

An A-type thin film transistor A-type TFT is a thin film transistor where the buffer layer 136 is omitted from the thin film transistor of FIG. 1. That is, the gate electrode 131 directly contacts the gate dielectric layer 141 in FIG. 1.

A B-type thin film transistor B-type TFT is formed with a form of the thin film transistor of FIG. 1. SiNx is used for the buffer layer 136.

In a C-type thin film transistor C-type TFT, the gate dielectric layer 141 is formed with a multi-layer and a silicon nitride layer is inserted between multi-layers of the gate dielectric layer in the thin film transistor shown in FIG. 1.

As shown in FIG. 6, in a case of the A-type thin film transistor A-type TFT, an unstable threshold voltage characteristic is shown at 60° C., and in a case of the C-type thin film transistor C-type TFT, an unstable threshold voltage characteristic is shown at a room temperature. Contrary to those, the B-type thin film transistor B-type TFT (i.e., a thin film transistor based on embodiments of the present invention) has a stable threshold voltage characteristic at a room temperature and a 60° C. temperature compared to the A and C type thin film transistors A-type TFT and C-type TFT of the comparison example.

According to embodiments of the present invention, interface defect between the gate dielectric layer and the active layer can be removed due to the buffer layer. Accordingly, interface characteristic is improved such that a thin film transistor with an improved reliability can be provided.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A thin film transistor comprising:
a substrate;
source/drain electrodes on the substrate;
an oxide active layer between the source/drain electrodes;
a gate electrode on one side of the oxide active layer;
a gate dielectric layer between the gate electrode and the oxide active layer; and
a buffer layer between the gate dielectric layer and the oxide active layer.

2. The thin film transistor of claim 1, wherein the buffer layer comprises a silicon oxide, a silicon nitride, or a combination thereof.

3. The thin film transistor of claim 2, wherein the buffer layer has a thickness of about 1 nm to about 20 nm.

4. The thin film transistor of claim 1, wherein:
the source/drain electrodes are disposed adjacent to the substrate;
the oxide active layer is disposed on the substrate between the source/drain electrodes;
the gate dielectric layer is disposed on the oxide active layer; and
the buffer layer is disposed between the oxide active layer and the gate dielectric layer.

5. The thin film transistor of claim 1, wherein:
the gate electrode is disposed adjacent to the substrate;
the gate dielectric layer and the buffer layer are sequentially stacked on the substrate including the gate electrode;
the oxide active layer is disposed on the buffer layer on the gate electrode; and
the source/drain electrodes are disposed on the buffer layer beside the active layer.

6. The thin film transistor of claim 1, wherein the oxide active layer comprises at least one oxide selected from Group 3A, 4A, and 5A, and Group 2B, 3B, and 4B metals.

7. The thin film transistor of claim 6, wherein the oxide active layer comprises at least one of ZnO, In—Zn—O, Zn—Sn—O, In—Ga—ZnO, Zn—In—Sn—O, In—Ga—O, and SnO₂.

8. The thin film transistor of claim 1, wherein the gate dielectric layer comprises alumina.

9. A method of forming a thin film transistor, the method comprising:
forming a source/drain electrode, a gate dielectric layer, a buffer layer contacting the gate dielectric layer, an oxide active layer, and a gate electrode, on a substrate; and
performing a thermal treatment process on the gate dielectric layer and the buffer layer, wherein:
the oxide active layer is formed on the substrate between the source/drain electrodes;
the gate dielectric layer is formed on side of the oxide active layer;
the buffer layer is formed on one side of the gate dielectric layer; and
the gate electrode is spaced apart from the oxide active layer by the gate dielectric layer.

10. The method of claim 9, wherein the forming of the source/drain electrodes, the gate dielectric layer, the buffer layer, the oxide active layer, and the gate electrode comprises:
forming the gate electrode on the substrate;
forming the gate dielectric layer and the buffer layer covering the gate electrode; and
forming the source/drain electrodes and the oxide active layer on the buffer layer at both sides of the gate electrode.

11. The method of claim 9, wherein the forming of the source/drain electrodes, the gate dielectric layer, the buffer layer, the oxide active layer, and the gate electrode comprises:
forming the source/drain electrodes and the oxide active layer on the substrate;
forming the buffer layer and the gate dielectric layer to cover the oxide active layer; and
forming the gate electrode on the gate dielectric layer.

12. The method of claim 9, wherein the thermal treatment is performed under a temperature of about 100° C. to about 300° C.

13. The method of claim 9, wherein the gate dielectric layer comprises alumina.

14. The method of claim 9, wherein the buffer layer comprises a silicon oxide, a silicon nitride, or a combination thereof, and is formed under a room temperature to a temperature of about 500° C.

15. The method of claim 14, wherein the buffer layer is formed through a plasma enhanced chemical vapour deposition method.

16. The method of claim 9, wherein the oxide active layer comprises at least one oxide selected from Group 3A, 4A, and 5A and Group 2B, 3B, and 4B metals.

17. The method of claim 9, wherein the gate electrode and the source/drain electrodes comprise at least one selected from a metal and a metal oxide.
